(19) United States
(12) Patent Application Publication
(10) Pub. No.: US 2006/0105148 A1
(43) Pub. Date: May 18, 2006

(54) Article with patterned layer on surface

(75) Inventors: Ronald S. Cok, Rochester, NY (US); Debasis Majumdar, Rochester, NY (US); Glen C. Irvin JR., Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 10/987,992

(22) Filed: Nov. 12, 2004

(51) Int. Cl. G03G 7/00

(52) U.S. Cl. 428/195.1; 428/917

(57) ABSTRACT

An article is described, comprising: a) a substrate having first regions having a microstructured surface and second regions not having a microstructured surface, where the first regions and second regions are relatively differentially wettable; and b) a patterned layer formed on the substrate from a coating that preferentially wets the relatively more wettable regions of the substrate. A method of making a patterned coating is also described, comprising the steps of: a) providing a substrate having first regions having a microstructured surface and second regions not having a microstructured surface, where the first regions and second regions are relatively differentially wettable; and b) coating the substrate with a coating material that preferentially wets the relatively more wettable regions of the substrate to form a patterned layer on the substrate.

### FIELD OF THE INVENTION

This invention relates to surfaces with fractal micro-features and more particularly, to patterned material deposition on surface with fractal micro-features.

### BACKGROUND OF THE INVENTION

The use of microstructured surfaces are known to affect the wetting properties of the surface and may be constructed to prevent the wetting of the surface. For example, US20020084290A1 entitled “Method and apparatus for dispensing small volume of liquid, such as with a wetting-resistant nozzle” by Materna, et al published 20020704 describes a wetting-resistant nozzle for accurately and precisely dispensing small volumes of liquids and describes the use of surface roughness to increase the hydrophobic character of the surface. Such microstructures may be formed with a mold. Means for creating such molds are known and described in, for example, US6641767 B2 entitled “Methods for replication, replicated articles, and replication tools” by Zhang et al, issued 20031104. US6641767B2 describes a method of replicating a structured surface that includes providing a tool having a structured surface having a surface morphology of a crystallized vapor deposited material; and replicating the structured surface of the tool to form a replicated article. A replicated article includes at least one replicated surface, wherein the replicated surface includes a replica of a crystallized vapor deposited material. A replication tool includes: a tool body that includes a tooling surface; and a structured surface on the tooling surface, wherein the structured surface includes crystallized vapor deposited material or a replica of crystallized vapor deposited material. US 2004/0026832 A1 by Gier et al published 20040212 describes an embossing method for producing a microstructured surface relief. Such molded or embossed microstructured surfaces typically have fractal or random surface structures having sizes in the nanometer to tens of microns range.

Alternatively, a random roughness microstructurerd surface having similar feature sizes in the nanometer to tens of microns range may be created by abrasive mechanical means such as sandblasting, abrasive water jet, rubbing with sandpaper or abrasive, and the like. It would also be possible to prepare a microstructured rough surface by adding material onto an originally manufactured smooth surface, such as by adhering grains of particulate matter of a suitable size using a suitable adhesive. Such coatings or abrading can be performed using rollers in contact with the surface.

In many continuous manufacturing processes, it is necessary to coat a continuous surface with a material. In many cases, such coatings must be patterned over the surface. Existing techniques for applying such patterned coatings, or patterning previously applied coatings, include ink-jet, ablation, and a variety of coating hoppers. However, such techniques are either expensive, slow, or are not readily employed for patterning continuous substrates.

There is a need therefore for an improved means to pattern a coated surface that reduces the cost of manufacture and improves the speed of manufacture.

### SUMMARY OF THE INVENTION

In accordance with one embodiment, the invention is directed towards an article comprising:

a) a substrate having first regions having a microstructured surface and second regions not having a microstructured surface, where the first regions and second regions are relatively differentially wettable; and

b) a patterned layer formed on the substrate from a coating that preferentially wets the relatively more wettable regions of the substrate.

In accordance with a further embodiment, the invention is directed towards a method of making a patterned coating, comprising the steps of:

a) providing a substrate having first regions having a microstructured surface and second regions not having a microstructured surface, where the first regions and second regions are relatively differentially wettable; and

b) coating the substrate with a coating material that preferentially wets the relatively more wettable regions of the substrate to form a patterned layer on the substrate.

### ADVANTAGES

Articles of the invention comprising a patterned layer on a surface have the advantage that they may be constructed at a high speed and at a low cost.

### BRIEF DESCRIPTION OF THE DRAWINGS

FIG. 1 is a schematic view of a microstructured patterned surface according to one embodiment of the present invention;

FIG. 2 is a schematic diagram illustrating a manufacturing process for manufacturing the surface illustrated in FIG. 1;

FIG. 3 is flow diagram for the process of FIG. 2; and

FIG. 4 is a schematic view of a surface having a patterned conductive coating according to an embodiment of the present invention.

### DETAILED DESCRIPTION OF THE INVENTION

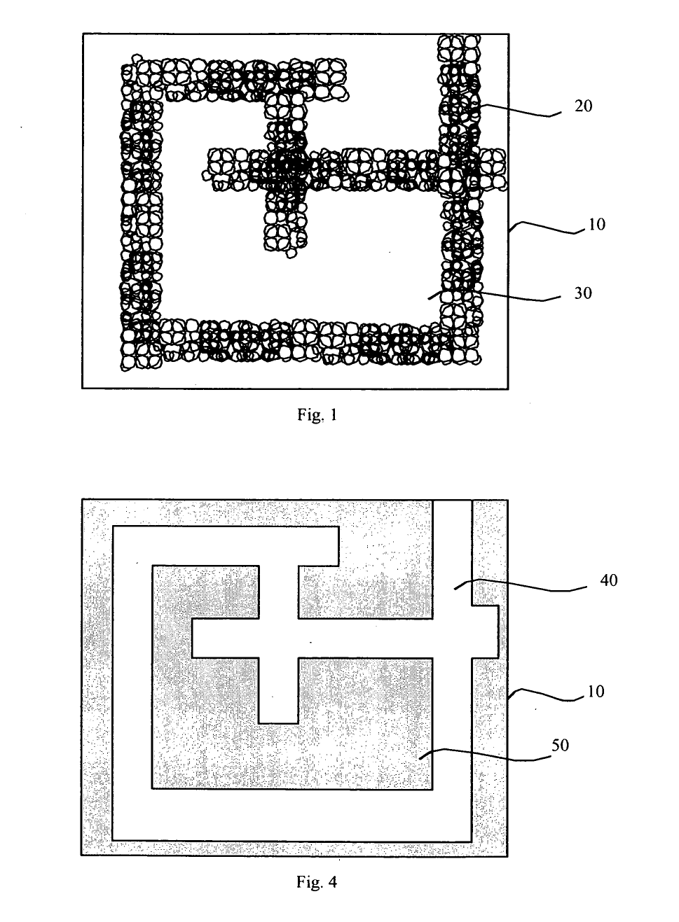

Referring to FIG. 1, the present invention comprises a substrate with a surface 10 having first regions 20 having a microstructured surface and second regions 30 not having a microstructured surface, where the first regions and second regions are relatively differentially wettable. Depending upon the type of material to be coated as a layer upon the surface 10, either the first or second region may be relatively more wettable than the other. For most coated layer materials, however, the second regions 30 not having microstructured surfaces will typically be more wettable than the first regions 20.

Substrate 10 may comprise rigid or flexible materials, may be transparent or opaque, and may be manufactured using continuous roll or batch processes. Materials such as glasses, plastics, and metals, e.g., may be employed. In a preferred embodiment, substrate 10 comprises a transparent polymeric material. Such plastic substrates may provide high light transmission properties, are inexpensive, and a sheet of polymeric material can be readily formed with microstructures. Suitable polymer materials include polyolefins, polyesters, polyamides, polycarbonates, cellulosic esters, polystyrene, polyvinyl resins, polysulfonamides, polyethers, polyimides, polyvinylidene chloride, polyvinylidene fluoride, polyurethanes, polyphenylenesulfides, polytetrafluoroethylene, polyacetals, polysulfonates, polyester ionomers, and polyolefin ionomers, as well as copolymers and blends thereof. Polyolefins, particularly polypropylene, polyethylene, polymethylpentene, and mixtures thereof may be particularly suitable. Polyolefin copolymers, including copolymers of propylene and ethylene such as hexene, butene and octene can also be used. Polyolefin polymers are suitable because they are low in cost and have good strength and surface properties and have been shown to be soft and scratch resistant. Polycarbonate polymers are also particularly suitable, as they have high light transmission and strength properties. Copolymers and/or mixtures of these polymers can be used. Applicants have constructed substrate surfaces having replicated fractal-like microstructures varying in size from 20 to 100 nm using polycarbonate and polyester substrate materials.

The size, shape, and locations of the microstructured surface areas may be optimized for specific applications. The microstructure features formed in the first regions 20 may be regularly arranged or may be random. For example, the profile of the microstructures can vary to complement a variety of materials so as to maximize the lifetime, clarity, and physical properties of the substrate material as well as the wettability of the regions. The substrate material may be transparent or opaque, rigid or flexible, for example glass, metal, metal foil, or plastic. In many applications, a transparent, flexible material is useful, particularly for display applications.

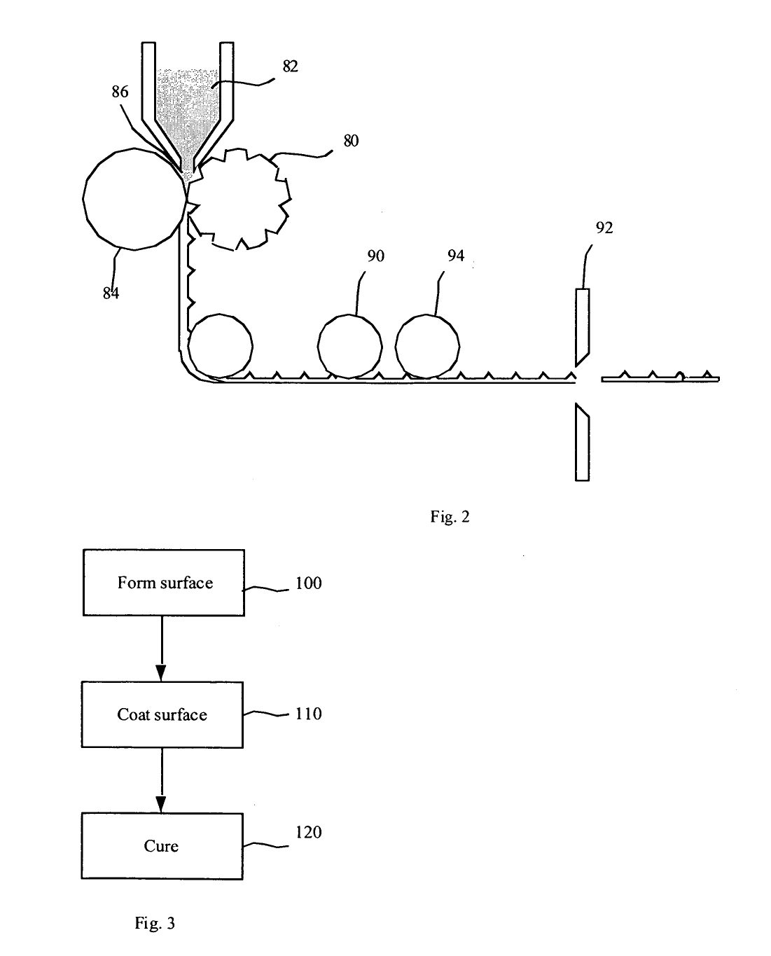

Referring to FIG. 2, in a preferred embodiment of the present invention, the microstructured surface regions, are formed in the substrate in an injection roll molding step of a substrate manufacturing process. In the injection roll molding process, a polymer 82 is heated above its melting point, and is injected under pressure into a nip 86 formed by a patterned roller 80 and an elastomer covered backing roller 84 in direct contact with the patterned roller 80. The patterned roller 80 has a pattern of cavities for forming the microstructures. As the polymer is injected into the nip 86, some of the melted polymer fills the cavities of the patterned roller to form the microstructures and the balance of the polymer is squeezed into a flat sheet: After the microstructured patterned surface has been formed, the surface is mechanically released from both of the rollers.

The microstructured surface regions may have self-similar fractal surface structures at a variety of different sizes. Such fractal surfaces are known to affect the wetting properties of the surface and may be constructed to prevent the wetting of the surface of any material molded with microstructures from the patterned roller 80. The microstructured surfaces once formed may be coated with a suitable material to further increase the hydrophobic or lyophobic nature of the surface. Suitable materials may be taken from classes of polymers including fluorocarbons, perfluorocarbons, polysiloxanes and mixtures thereof. For example, TEFLON™ (polytetrafluoroethylene) is a widely-known and available hydrophobic material with low surface energy. Such materials may be added prior to the microstructured patterning step in specific locations or onto specific locations after the patterned roller has formed such microstructures.

Referring to FIG. 3, once a substrate with a surface having suitably patterned microstructures is provided 100, the surface is coated 110 with a material to form a patterned layer. Any material having suitable wetting characteristics matched to the microstructure surface may be employed. The material applied to the surface will preferentially spread over the relatively more wettable areas of the surface in contrast to the microstructured region, thus forming a patterned coating on the surface. In a preferred embodiment, the coated material comprises an electrically conductive polymer, such as substituted or unsubstituted polythiophenes, substituted or unsubstituted polypyrrole, and substituted or unsubstituted polyaniline. Preferred electrically conducting polymers for the present invention include polypyrrole styrene sulfonate (referred to as polypyrrole/poly (styrene sulfonic acid) in U.S. Pat. No. 5,674,654), 3,4-dialkoxy substituted polypyrrole styrene sulfonate, and 3,4-dialkoxy substituted polythiophene styrene sulfonate. The most preferred substituted electronically conductive polymers include poly(3,4-ethylene dioxythiophene styrene sulfonate). The coated layer may be applied to the substrate surface using a variety of coating means, for example rollers 90 (FIG. 2). Suitable coating methods including curtain coating, roll coating and spin coating, slide coating, blade coating, electro-photographic coating and spin coating. The surface on which the conductive material is deposited can be pre-treated for improved adhesion by any of the means known in the art, such as acid etching, flame treatment, corona discharge treatment, glow discharge treatment or can be coated with a suitable primer layer. However, corona discharge treatment is the preferred means for adhesion promotion.

The coating may then be dried or cured 120, for example by heat with a heated roller 94 (FIG. 2), radiation such as ultra-violet light, or drying in a dry atmosphere to form a patterned conductive coating with localized areas of conductivity and other areas with no conductivity. Finally, the web may be cut with knives 92 into individual sheets. Referring to FIG. 4, the pattern of FIG. 1 forms a patterned layer comprising conductive area 50, and a non-conductive area 40 on the surface 10.

The pattern-coated substrate of the present invention can be integrated into a flat-panel display by using either the cover or the substrate of the flat-panel display as the substrate surface 10. The flat-panel display may emit light through a transparent cover or through a transparent substrate. For example, patterned conductive coatings obtained in accordance with the invention may provide electrical conductivity within a flat-panel display, such as an OLED display, or within an electrically operated touch screen. Electrical devices or conductors may be applied to the substrate surface 10 in electrical connection to the patterned coating.

Injection roll molding has been shown to more efficiently replicate the desired microstructures compared to embossing and vacuum forming. It is further contemplated that the surface may be cut into the desired size for application to an LCD or OLED flat-panel display, for example. The present invention may be used in conjunction with any flat-panel display, including but not limited to OLED and liquid crystal display devices.

Alternatively means to form a patterned microstructured surface include abrasive mechanical means such as sandblasting, abrasive water jet, rubbing with sandpaper or abrasive, and the like. It is also possible to prepare a rough microstructured patterned surface by adding material onto an originally manufactured smooth surface, such as by adhering grains of particulate matter of a suitable size using a suitable adhesive. Such patterned coatings or abrading can be performed using rollers in contact with the surface.

The entire contents of the patents and other publications referred to in this specification are incorporated herein by reference.

The invention has been described in detail with particular reference to certain preferred embodiments thereof, but it will be understood that variations and modifications can be effected within the spirit and scope of the invention.

### PARTS LIST

10 substrate surface
20 first region
30 second region
40 non-conductive region
50 coated conductive patterned layer region
80 patterned roller
82 polymer
84 backing roller
86 nip
90 coating roller
92 knife
94 heat roller
100 form surface step
110 coat step
120 cure step

1. An article comprising:
a) a substrate having first regions having a microstructured surface and second regions not having a microstructured surface, where the first regions and second regions are relatively differentially wettable; and
b) a patterned layer formed on the substrate from a coating that preferentially wets the relatively more wettable regions of the substrate.

2. The article claimed in claim 1, wherein the patterned layer comprises a conductive polymer pattern deposited on the substrate surface.

3. The article claimed in claim 2, wherein the relatively more wettable regions of the substrate comprise the second regions not having a microstructured surface.

4. The article of claim 2, wherein the conductive polymer comprises polythiophene.

5. The article claimed in claim 2, further comprising electronic components electrically connected by the conductive polymer pattern.

6. The article claimed in claim 2, further comprising display components formed over the substrate surface.

7. The article claimed in claim 6 wherein the display components are OLED components.

8. The article claimed in claim 7 wherein the conductive polymer pattern forms electrodes for the OLED components.

9. The article claimed in claim 1, wherein the substrate is flexible.

10. The article claimed in claim 1, wherein the substrate is plastic.

11. The article claimed in claim 1, wherein the substrate is rigid.

12. The article claimed in claim 1, wherein the substrate is glass.

13. The article claimed in claim 1, wherein the substrate is metal.

14. The article claimed in claim 1, wherein the substrate is planar.

15. The article claimed in claim 1, wherein the relatively more wettable regions of the substrate comprise the second regions not having a microstructured surface.

16. The article of claim 1, wherein the substrate is transparent.

17. A method of making a patterned coating, comprising the steps of:
a) providing a substrate having first regions having a microstructured surface and second regions not having a microstructured surface, where the first regions and second regions are relatively differentially wettable;
b) coating the substrate with a coating material that preferentially wets the relatively more wettable regions of the substrate to form a patterned layer on the substrate.

18. The method of claim 17 further comprising curing the coated patterned layer material.

19. The method claimed in claim 18, wherein the cure is one of the group including: a heat cure, an ultra-violet cure, and a drying cure.

20. The method claimed in claim 17, wherein the coating material comprises a conductive material.

21. The method claimed in claim 20, wherein the coating material comprises a conductive polymer.

22. The method claimed in claim 17, wherein the microstructured surface is molded into the substrate.

23. The method claimed in claim 22, wherein the microstructured surface is formed at the same time as the substrate by injection roll molding.

24. The method claimed in claim 17, wherein the microstructured surface is formed by abrasion.

25. The method claimed in claim 17, wherein the microstructured surface is formed by adhering grains of particulate matter to the substrate.
